(19) United States
(12) Patent Application Publication
(10) Pub. No.: US 2005/0130384 A1
(43) Pub. Date: Jun. 16, 2005

(54) Method for manufacturing resistor of a semiconductor device

(75) Inventor: Yi-Sun Chung, Chungcheongbuk-do (KR)

Correspondence Address: MARSHALL, GERSTEIN & BORUN LLP, 6300 SEARS TOWER, 233 S. WACKER DRIVE, CHICAGO, IL, 60606, US

(73) Assignee: HYNIX SEMICONDUCTOR INC., Kyungki-Do (KR)

(21) Appl. No.: 10/988,008

(22) Filed: Nov. 12, 2004

(30) Foreign Application Priority Data
Dec. 11, 2003 (KR) 2003-79834

(51) Int. Cl. H01L 21/20

(52) U.S. Cl. 438/384

(57) ABSTRACT

The present invention discloses a method for manufacturing a resistor of a semiconductor device. In the manufacture of a resistor made of polysilicon, a polysilicon film of a fine grain structure is formed on the top of a semiconductor substrate at a temperature of more than 700° C., or a fine grain polysilicon film with heteronuclei produced therein is formed by depositing a polysilicon to a first height and purging the same and then depositing a polysilicon to a second height and purging the same. After doping the fine grain polysilicon film with a dopant and thermally treating the same, the polysilicon is patterned to form a resistor pattern. Accordingly, the resistor of this invention has an even distribution as the gradient in the dopant concentration becomes smaller by fine grains in the polysilicon film.

### BACKGROUND OF THE INVENTION

1. Field of the Invention

The present invention relates to a method for manufacturing a resistor of a semiconductor device, and more particularly, to a method for manufacturing a resistor of a semiconductor device which can improve the characteristics of mixed signals and RF devices by making the dopant concentration in polysilicon more even to form a resistor.

2. Description of the Related Art

In general, resistors made of polysilicon have advantages over diffusion resistors in that they have excellent temperature characteristics and occupy a small surface area in the manufacture of a device.

Polysilicon resistors are divided into general resistors and high resistors (HR) depending upon the degree of doping of polysilicon used as a gate electrode after the manufacture process of a gate oxide film. As with general resistors, used are ones with polysilicon doped at a dopant concentration of about E15/cm², while, as with the high resistors, used are ones with polysilicon doped at a concentration of ˜E14/cm² which is lower than that of general resistors.

FIGS. 1a to 1d are process charts sequentially showing the process of manufacturing a resistor in accordance with a prior art resistor manufacture method. Referring to these drawings, the method for manufacturing a resistor in accordance with the prior art will be described.

First, as shown in FIG. 1a, a silicon oxide (SiO₂) film as an insulating film 12 is formed on the top of a silicon substrate as a semiconductor substrate 10. A polysilicon film 14 as a conductive film, which is to be used as a resistor, is deposited over the silicon oxide film.

Next, as shown in FIG. 1b, a high resistor portion is masked for the sake of a general resistor to which a silicide process has not been performed yet, and a polysilicon film 16 at a general resistor portion is opened and doped with an n+/p+ dopant at a high concentration of about E15/cm². Alternatively, as shown in FIG. 1c, a general resistor portion is masked for the sake of a high resistor, and a polysilicon film 18 at a high resistor portion is opened and doped with a p− dopant at a low concentration of ˜E14/cm².

Continually, after diffusing the doped dopant to the polysilicon film by a thermal treating process, the polysilicon film is patterned by an etching process using a resistor mask to define a general resistor pattern 16 or a high resistor pattern 18.

Next, as shown in FIG. 1d, an interlayer insulating film 20 is deposited all over the top surfaces of the general resistor pattern 16 and high resistor pattern 18, and contact electrodes 22 and wires 24, that are to be vertically connected to those resistor patterns 16 and 18 through the interlayer insulating film 20, are formed.

By the way, in the manufacture process of a resistor in the prior art, the doping concentration of a general resistor or of a high resistor may be in accordance with a target resistance coefficient. But, a polysilicon film has a column structure because it is mostly deposited at a temperature of about 600° C. Such a column structure is poorer than a fine grain structure from the resistance aspect, and has a low doping concentration. Besides, where a subsequent thermal treatment is not enough, a doping change in the grains is increased due to the large size of the fine grain structure.

In the meantime, also in the resistors of mix signals and RF devices, there is a large demand for the improvement of VCR (Voltage Coefficient Variation) and TCR (Temperature Coefficient Variation) for a signal matching. However, the conventional resistor is problematic in that a dopant concentration change is irregular due to the column structure of a polysilicon film and accordingly, the linear characteristic, which is considered very important in mix signals and RF devices and the like, is deteriorated.

### SUMMARY OF THE INVENTION

The present invention is designed in consideration of the problems of the prior art, and therefore it is an object of the present invention to provide a method for manufacturing a resistor of a semiconductor device, which forms the grains in a polysilicon film into fine particles to make the dopant concentration even and improve the linear characteristic of mix signals and RF devices by depositing polysilicon at a high temperature of more than 700° C. or depositing polysilicon to a predetermined thickness at 600° C. and then repeating the process of stopping deposition with a purge, in the formation of a polysilicon resistor.

To achieve the above object, there is provided a method for manufacturing a resistor of a semiconductor device in accordance with the present invention, comprising the steps of: forming a fine grain structure by depositing a polysilicon on the top of a semiconductor substrate at a temperature of 700 to 1000° C.; doping the polysilicon with a dopant and thermally treating the same; and forming a resistor pattern by patterning the polysilicon.

### BRIEF DESCRIPTION OF THE DRAWINGS

Other objects and aspects of the present invention will become apparent from the following description of the embodiments with reference to the accompanying drawings in which:

FIGS. 1a to 1d are process charts showing a method for manufacturing a resistor in accordance with the prior art;

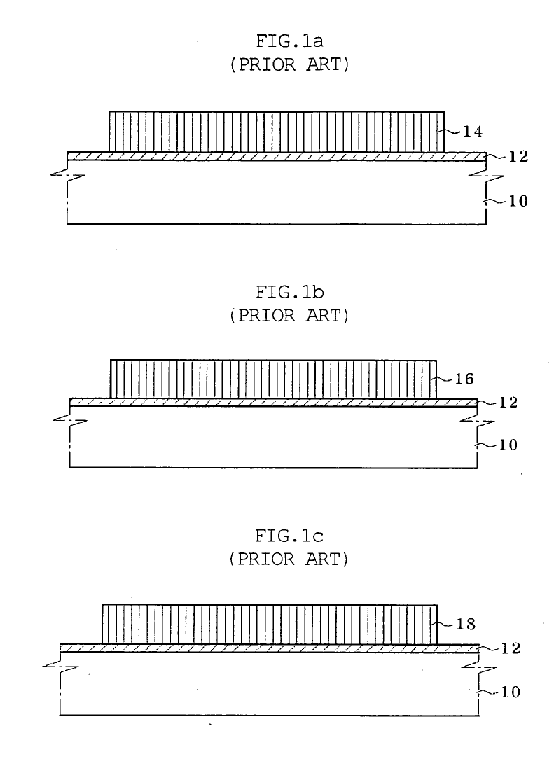

FIGS. 2a to 2d are process charts showing a method for manufacturing a resistor in accordance with the present invention;

FIGS. 3a to 3b are views comparing fine grain structures of polysilicon films in resistors in the prior art and in accordance with the present invention;

FIGS. 4a and 4b are views showing a process of manufacturing a polysilicon film of a resistor in accordance with one embodiment of the present invention; and

FIGS. 5 to 5d are views showing a process of manufacturing a polysilicon film of a resistor in accordance with another embodiment of the present invention.

### DESCRIPTION OF THE PREFERRED EMBODIMENT

Hereinafter, a preferred embodiment of the present invention will be described in more detail referring to the drawings.

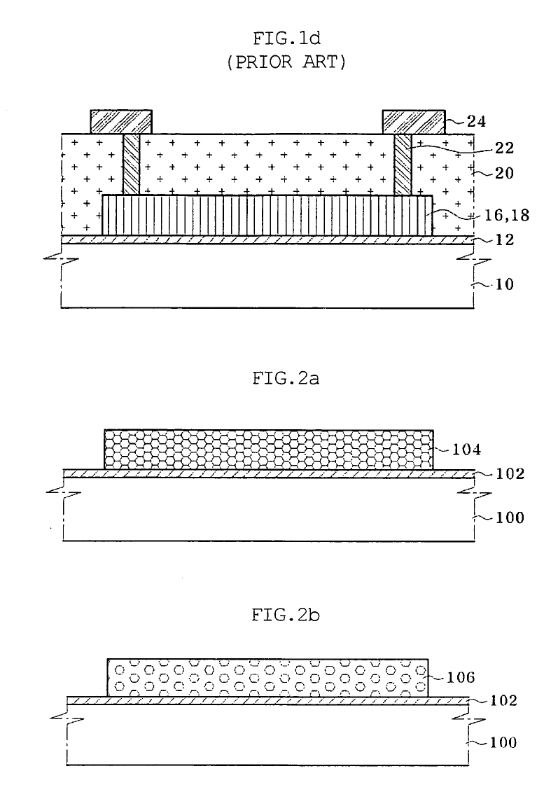

FIGS. 2a to 2d are process charts sequentially showing a method for manufacturing a resistor in accordance with the present invention. Referring to these drawings, the method for manufacturing a resistor in accordance with the present invention will be described.

First, as shown in FIG. 2a, a silicon oxide (SiO₂) film as an insulating film 102 is formed on the top of a silicon substrate as a semiconductor substrate 100. A polysilicon film 104 as a conductive film, which is to be used as a resistor, is deposited over the silicon oxide film. In the deposition of the polysilicon film 104, a high temperature deposition of more than 700° C. is carried out to increase nuclei growth rather than nucleation, thereby forming a polysilicon film 104 of a fine grain structure. Alternatively, after the deposition of the polysilicon film 104 to a predetermined thickness at a temperature of 600° C. as in the prior art, a purge process is repeated to create multiple fine heteronuclear sites, thereby forming a polysilicon film 104 of a fine grain structure.

Next, as shown in FIG. 2b, a high resistor portion is masked for the sake of a general resistor to which a silicide process has not been performed yet, and a polysilicon film 106 of a fine grain structure at a general resistor portion is opened and doped with a n+/p+ dopant at a high concentration of about E15/cm². Alternatively, as shown in FIG. 2c, a general resistor portion is masked for the sake of the high resistor, and a polysilicon film 108 of a fine grain structure at a high resistor portion is opened and doped with a p− dopant at a low concentration of ˜E14/cm². The doping energy ranges from 20 keV to 60 keV.

In the meantime, in order to prevent the out-diffusion of a dopant, the high resistor polysilicon film 108 may be additionally doped with a low quantity of a carbon dopant in a subsequent thermal treating process.

Next, after diffusing the dopant to the polysilicon film by a thermal treating process, the polysilicon film is patterned by an etching process using a resistor mask to define a general resistor pattern 106 or a high resistor pattern 108. Whereupon, the polysilicon of the fine grain structure has a smaller grain size than a prior art polysilicon of a column structure does. Thus, in a doping process, the distribution of the dopant concentration in the present invention becomes more even than that of polysilicon of a column structure.

Next, as shown in FIG. 2d, an interlayer insulating film 110 is deposited all over the top surface of the general resistor pattern 106 and high resistor pattern 108, and contact electrodes 112 and wires 114, that are to be vertically connected to those resistor patterns 106 and 108 through the interlayer insulating film 110, are formed.

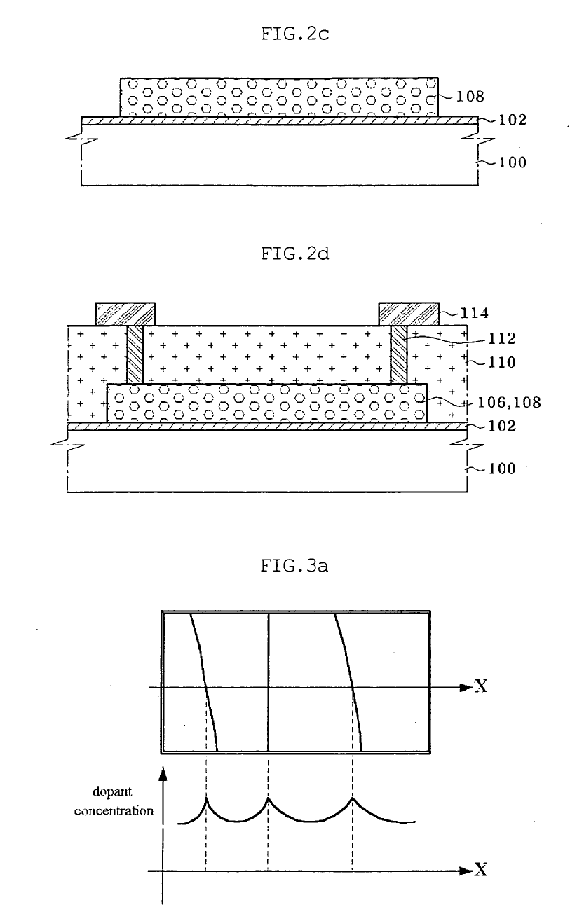

FIGS. 3a to 3b are views comparing fine grain structures of polysilicon films in resistors in the prior art and in accordance with the present invention. In these drawings, the y-axis represents the concentration of a dopant in a polysilicon film, and the x-axis represents a doped region.

Referring to FIG. 3a, the polysilicon film in the prior art is of a column structure, thus the dopant concentration is unevenly distributed in the film. On the contrary, as shown in FIG. 3b, the polysilicon film of the present invention is of a fine grain structure, thus it can be found that the dopant concentration is evenly distributed in the film.

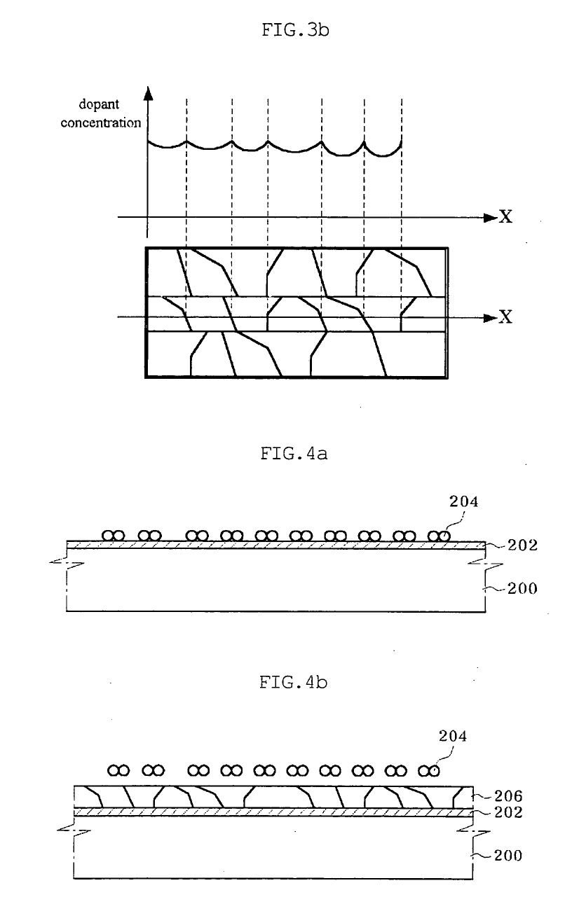

FIGS. 4a and 4b are views showing the process of manufacturing a polysilicon film of a resistor in accordance with one embodiment of the present invention. In these drawings, an example of adapting a high temperature process in the deposition process of the polysilicon film in accordance with the present invention is illustrated.

First, as shown in FIGS. 4a and 4b, a polysilicon is deposited on the top of a semiconductor substrate 200 having an interlayer insulating film 202 at a temperature of 700 to 1000° C., to form a polysilicon film 206 having a fine grain structure.

In this way, the polysilicon deposition in this embodiment is carried out at a temperature of 700 to 1000° C. which is higher than a typical polysilicon deposition temperature 600° C., to thus greatly increase the number of creation of nuclei 204 rather than the number of growth of nuclei 204, thereby forming a fine grain structure.

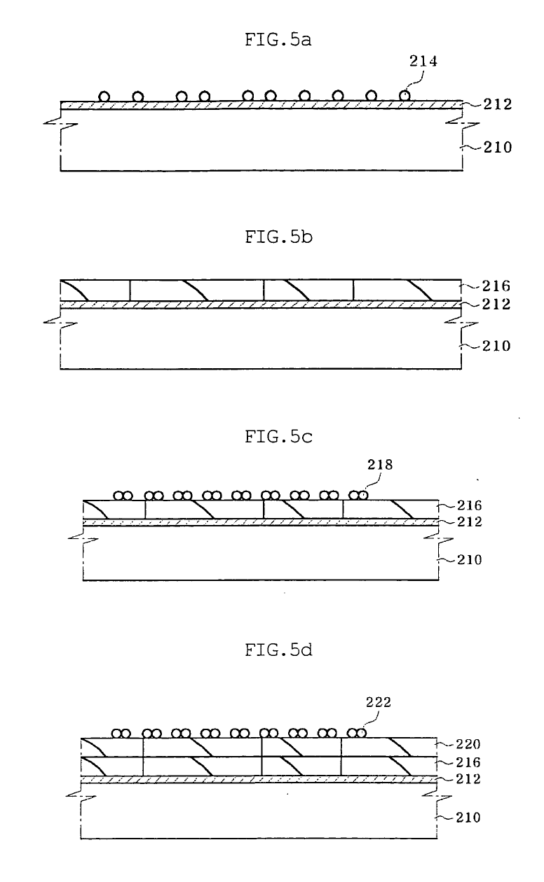

FIGS. 5a to 5d are views showing a process of manufacturing a polysilicon film of a resistor in accordance with another embodiment of the present invention. In the manufacture process of polysilicon in this embodiment, polysilicon is deposited at a temperature of 600° C., which is the same as a prior art polysilicon deposition temperature, and deposition and purging are repeated as follows.

As shown in FIGS. 5a to 5b, a polysilicon is deposited on the top of a semiconductor substrate 210 having an interlayer insulating film 212, i.e., a polysilicon 216 is deposited to a first height of 100 to 500 Å and then purged.

Then, as shown in FIGS. 5c to 5d, a polysilicon 210 is deposited to a second height of 100 to 500 Å and then purged.

In this manner, as the deposition and purging of polysilicon is repeated, the sites of fine heteronuclei 214, 218 and 222 are produced and the number of nuclei is greatly increased, thereby forming polysilicon films 212, 216 and 210 of a fine grain structure. At this time, a Si deposition method and temperature can be varied in many ways. That is, the grain size can be smaller even if the deposition temperature is low (200 to 600° C.) because heteronuclei can be produced using an interface, and a low temperature ALD, a deposition method using plasma and the like as well as a typical CVD can be employed.

As explained in preferred and other embodiments of the present invention, a resistor pattern of a polysilicon film can be formed by adapting a manufacture process of FIGS. 2b to 2d to a polysilicion film of a fine grain structure.

As seen from above, in the present invention, grains in a polysilicon film are formed into fine particles and a gradient in dopant concentration becomes smaller and even by depositing polysilicon at a high temperature of more than 700° C. or depositing polysilicon to a predetermined thickness at 600° C. and then repeating the process of stopping deposition by a purge, in the formation of a polysilicon resistor.

Accordingly, the present invention can ensure the linear characteristic of a resistor of mix signals and RF devices since the VCR and TCR characteristics of the resistor can be improved.

1. A method for manufacturing a resistor of a semiconductor device, comprising the steps of:
forming a fine grain structure by depositing a polysilicon on the top of a semiconductor substrate at a temperature of 700 to 1000° C.;
doping the polysilicon with a dopant and thermally treating the same; and
forming a resistor pattern by patterning the polysilicon.

2. The method of claim 1, wherein the doping step is carried out in the range of concentration of E13/cm² to E14/cm² and with an energy size of 20 keV to 60 keV.

3. A method for manufacturing a resistor of a semiconductor device, comprising the steps of:
forming a polysilicon film with heteronuclei produced therein by depositing a polysilicon on the top of a semiconductor substrate to a first height and purging the same and then depositing a polysilicon to a second height and purging the same;
doping the polysilcon with a dopant and thermally treating the same; and
forming a resistor pattern by patterning the same.

4. The method of claim 3, wherein the doping step is carried out in the range of concentration of E13/cm² to E14/cm² and with an energy size of 20 keV to 60 keV.

5. The method of claim 3, wherein the first and second heights of the polysilicon are 100 to 500° C. respectively.

6. The method of claim 3, wherein the grain size is formed smaller by a deposition at a low temperature of 200 to 600° C.

7. The method of claim 3, wherein the deposition is carried out by either a CVD, a low temperature ALD or a plasma deposition.
